(19) United States
(12) Patent Application Publication
(10) Pub. No.: US 2006/0024861 A1
(43) Pub. Date: Feb. 2, 2006

(54) Interposer structures and improved processes for use in probe technologies for semiconductor manufacturing

(75) Inventors: Steven A. Cordes, Yorktown Heights, NY (US); Matthew J. Farinelli, New York, NY (US); Sherif A. Goma, White Plains, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: International Business Machines Corporation, Armonk, NY (US)

(21) Appl. No.: 10/909,111

(22) Filed: Jul. 30, 2004

(51) Int. Cl. H01L 21/50; H01L 21/48; H01L 21/44

(52) U.S. Cl. 438/106

(57) ABSTRACT

Systems and method for making flexible and rigid interposers for use in the semiconductor industry. Electroless plating processes are used to minimize the costs associated with the production of flexible interposers while increasing the yield and life-cycle of the interposers. Electrical contact regions are more easily isolated using the electroless processes and risk of corrosion is reduced because all portions of the interposer are plated at once. Leads projecting from the flexible portion of the interposers accommodate a greater variety of components to be tested. The rigid interposers include a pin projecting from a probe pad affixed to a substrate. The pin is aligned with conductive vias in the underlying wafer. The rigidity of the pin penetrates oxides on a contact pad to be tested. Readily available semiconductor materials and processes are used to manufacture the flexible and rigid interposers according to the invention. The flexible and rigid interposers can accommodate pitches of as little as 25 μm.

### BACKGROUND OF THE INVENTION

1. Field of the Invention

This invention relates to the fabrication of interposers used in probing wafers for semiconductor manufacturing.

2. Prior Art

One of the final stages in the fabrication of integrated circuits on semiconductor wafers is the testing and sorting of the functionality of the circuits. The purpose of testing chips is to determine if the chips function as it was designed for; meaning that for given inputs, desirable outputs result. Sorting of chips is similar, but chips are specifically ranked in terms of how well each chip functions, for example, with respect to speed. Based on random variables, different chips will function at different speeds.

There are a variety of techniques employed for testing chips. One key factor in determining what process to use to test a chip is the complexity of the chip. The number of input and output (I/O) pads present on a chip are often representative of the complexity of the chip, wherein higher I/O numbers are attributed to higher chip complexity.

Low I/O chips with linear arrays of pads can be tested using probe stations where individual leads are brought into contact with each pad mechanically to provide power and signals, and to measure the outputs. For mid-range I/O chips, probe cards with many leads can be generated wherein the leads are arranged to correspond to each pad on the mid-range chip. The probe cards may also be wired and plugged into electronics for driving and measuring the performance of the chip. For high I/O chips, i.e., those having hundreds to thousands of I/O, with pads in aerial array rather than in linear array, connections to the testing electronics is impractical and expensive, and in some instances impossible.

Where testing or measuring of the chips is impractical, it is often advantageous to use packaging mounts, e.g., ceramic or organic modules in which the chips are mounted, in order to measure the chips. In this way, the wiring from the chip to electronics-compatible pins are already available. Temporary connections of the chips to the packaging mounts is preferred in order to avoid de-bonding a chip determined to be defective upon testing.

Interposers are devices commonly used for temporary connections in manufacturing for the probing of semiconductor wafers. FIG. 1 shows an interposer 100 that provides an electrical connection to an electronic component 110 for probing a wafer 120. Such interposers offer a convenient way of testing components, such as wafers, without requiring a permanent electrical connection, such as solder bonds, between the components. Permanent connection would have to be dismantled were the tested component deemed defective. Thus, such interposers often represent one method of helping to determine the functionality of wafers or chips in the semiconductor industry.

Current interposers used in probe technologies may be electrolytic plated flexible interposers designed to probe rigid, non-even surfaces such as those commonly associated with ceramic packaging modules. Current interposers may also be flexible interposers that, while easily implemented in a manufacturing environment, are difficult and cost-prohibitive to fabricate requiring unusual processing techniques that are not readily practiced. The variety of current interposers commercially available in the probe technologies tend to target rigid substrates, such as silicon chips. Thus in addition to the deficiencies cited above with respect to interposers used to probe rigid substrates, current interposers also fail to facilitate the probing of flexible substrates that are becoming more and more common in organic semiconductors.

### SUMMARY OF THE INVENTION

The present invention comprises systems and methods for fabricating interposer probes in a cost-effective and convenient manner for use with rigid or flexible substrates.

Some embodiments of the present invention comprise systems and methods for fabricating flexible interposers while reducing external power supply needs. These embodiments of the invention further comprise systems and methods for fabricating flexible interposer probes while reducing precious metals waste. These embodiments of the present invention further comprise systems and methods for fabricating flexible interposer probes with minimal nodule formations. These embodiments of the invention further comprises systems and methods for fabricating electrolessly plated flexible interposer probes using commercially available electroless metal baths.

Other embodiments of the present invention comprise systems and methods for fabricating flexible interposers using standard semiconductor processes improve yield and reduce costs. These embodiments of the invention provide for tighter pitches in the interposers than do current technologies, and better facilitate the probing of nonuniform substrate surfaces.

Still other embodiments of the present invention comprise systems and methods of fabricating a rigid interposer. The rigid interposer of these embodiments of the systems and methods of the present invention better facilitates the probing of flexible substrates.

The artisan should appreciate that interposers can be designed to reduce oxidation of components, to increase flexibility of components, and to overcome mismatch between connected components. Accordingly, the interposers fabricated by the systems and methods of the present invention, as described herein, are understood to accommodate these aspects as well.

The above and other features of the present invention, including various novel details of construction and combination of parts, will be more particularly described with reference to the accompanying drawings and claims. It will be understood that the various embodiments of the invention described herein are shown by way of illustration only and not as a limitation thereof. The principles and features of the invention may be employed in various alternative embodiments without departing from the scope of the invention.

### BRIEF DESCRIPTION OF THE DRAWINGS

These and other features, aspects and advantages of the systems and methods of the invention will become better understood with regard to the following description, drawings, and appended claims, wherein:

FIG. 1 illustrates a conventional flexible interposer connecting an electronic component to a wafer;

FIG. 2 illustrates an SEM micrograph of a cross section of a surface of an electrolessly plated probe according to the invention;

FIG. 3 illustrates a scanned image of an electroless plated probe after greyscale plating;

FIGS. 4A-4H illustrate another process for fabricating flexible interposers according to the invention;

FIGS. 5A-5F illustrate a process for fabricating rigid interposers according to the invention; and

FIG. 6 illustrates an embodiment of a probe for use with a rigid interposer according to the invention.

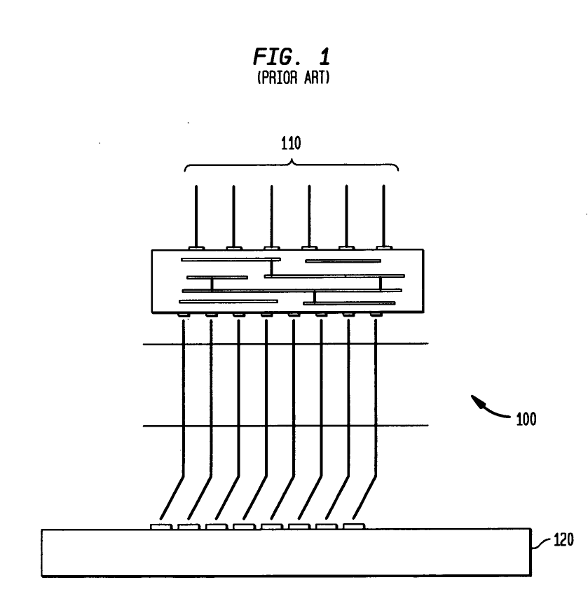

### DETAILED DESCRIPTION OF THE INVENTION

Electroless plating refers to the autocatalytic reduction of a metal ion at a cathodic surface. The metal ion in solution reduces at the surface of the workpiece through a parallel oxidation reaction. For example, a hypophosphite anion can be oxidized according to the following reaction:

$$\frac{\begin{matrix}{Ni}^{2 +} + 2 {e}^{-} -> {Ni}^{0} \\ {H}_{2} {PO}_{2}^{-} + {H}_{2} O -> {H}_{2} {PO}_{3}^{-} + 2 {H}^{+} + 2 {e}^{-}\end{matrix}}{{Ni}^{2 +} + {H}_{2} {PO}_{2}^{-} + {H}_{2} O -> {Ni}_{( metal )} + 2 {H}^{+} + {H}_{2} {PO}_{3}^{-}} \qquad Equation 1$$

Equation 1 renders hydrogen evolution as a result of the plating process. Excess hydrogen production can interfere with the quality of the plated film, however, and should be avoided by proper bath agitation. Commercially available electroless solutions contain stabilizers to control the reaction rates of Equation 1. Electroless plating baths also contain various metal salts, reducing agents and organics to buffer and maintain the solution as well as to adjust properties such as hardness and the appearance of deposits in the plating film. The advantage of the reaction of Equation 1 is that is does not rely on an external supply of electrons to reduce the metal ions. As a result, conformal depositions may occur on any active surface.

Some embodiments of this invention comprise an electroless plating process for fabricating flexible interposer probes. According to these embodiments, the electroless plating process uses conformal metal coatings without external power supplies or complicated commoning methods. Because no external power source is used, nodule formations are minimized. Such nodule formations tend to occur at points of high current densities, e.g., at sharp edges, when forming flexible interposer probes using standard electrolytic plating techniques. Further, because the electroless plating solutions of the invention contact all parts of the interposer probe, electrically isolated regions need not be attached to one another by a commoning layer, such as a thin film deposition of Cu, for example. Further still, the electroless plating techniques described herein improve the manufacturability and reduce the cost of interposers as compared to known interposer fabricating technologies.

Electroless plating, according to the present invention, begins by forming a surface that is clean and catalytic. The artisan will appreciate that numerous techniques exist for creating an autocatalytic surface with a variety of chemicals, though for brevity the discussion herein focuses on those chemicals most suited for electroless deposition on copper as most probe panels use copper as its plating surface. The standard method of creating a catalytic surface is by utilizing an immersion, or displacement, deposit of a more noble and catalytic metal such as zinc (Zn), palladium (Pd), or tin (Sn).

Displacement deposits occur when a metal surface with a lower free energy, i.e., less noble, is placed into a solution containing metal ions that are at a higher free energy, i.e., more noble. The difference in the thermodynamic free energies drives the reaction that replaces the metal atom on the surface with the metal atoms from the solution. The kinetics of the reaction are governed by the fractional surface coverage of the replacement atom on the surface. As the fractional coverage of the surface increases, the reaction slows down. A typical example of this reaction is that of a Cu metal surface being displaced by Pd atoms from an acidic solution. The reaction is described by Equation 2 below:

$$Cu + {Pd}^{ 2 +} + {SO}_{4}^{2 -} {\to }^{pH < 7} Pd + {Cu}^{2 +} + {SO}_{4}^{2 -} \qquad Equation 2$$

In the above reaction described by Equation 2, the Cu atoms on the plating surface are displaced by the Pd atom because of a reaction potential of −1.293 V driving the Pd atom to cover the surface. The pH of the solution is adjusted to be acidic by the addition of sulfuric acid, for example. The acid helps to prevent oxidation at the Cu surface and favors the removal of Cu metal as copper sulfate. The reaction of Equation 2 will cease once the surface has been fully covered with Pd atoms. Immersion deposits can range from a few hundreds of angstroms to a few microns in thickness depending on the metal systems used.

Table 1 below illustrates chemistries and processes used in the production of electroless plated probes according to some embodiments of the invention.

TABLE 1
Electroless plating chemistries used in the production of probes.
Cu Preclean Procedure: Strip all resist coatings, Soak in Ethyl
Alcohol with ultrasonic agitation for 5 minutes, DI Water Rinse,
Oxygen Ash at 100 W for 5 min in 650 mTorr of O2

| ENPLATE NI426 | Oromerse MN | Gobright TMX-21 |
|---|---|---|
| Operating | Operating | Operating |
| temperature: 83 C. | Temperature: 70 C. | Temperature: 55 C. |
| Operating pH = 6.2 | Operating pH = 5.5 | Operating pH = 7.4 |
| Optimal plating | Optimal plating | Optimal Plating |
| rate = 15-18 μm/hr @85 C. | rate = 5-7 nm/min | Rate = 1.5 μm/hour |
| | Maximum Au | Minimal part |
| | Thickness = 0.3 μm | agitation |

There are five primary steps to the electroless plating process according to the invention. The steps generally are:

1. pre-cleaning the sample

2. seeding the sample

3. depositing an electroless layer on the sample

4. immersion seeding the sample

5. depositing the electroless on the sample,

for example, wherein the initial seeding is Pd seeding, the initial electroless layer Ni, the immersion seeding is Au, and last electroless layer is Au.

The electroless deposition process starts with a probe panel produced according to a standard process recipe except that a Ni/Au bump plating step is omitted. Protection of the Cu bumps from greyscale etching solution is important and may be achieved by applying some spin-on photoresist or dry film laminate. Probes are individually cut from the four-up panel configurations and loaded onto a custom designed, Delrin® probe holder. The probe holder is made completely of polymer materials to avoid plating onto any metal parts. The sample is fixed by its dowel pin holes and held in a semi-rigid manner. Holding the sample in this manner helps keep the probe in a steady position in the baths.

Experimentation of the processes according to the present invention has determined that a clean Cu surface is required for proper Pd seeding and electroless Ni deposition. It is also preferable to strip any organics from the Cu surfaces because the probes are treated with a benzotriazole solution and other organic chemicals during their production. Panels are stripped of any photoresist, soaked in ethyl alcohol and rinsed in de-ionized (DI) water. The parts are then be oxygen ashed prior to plating to remove any residual organic compounds. A Branson® barrel asher operating at a frequency of 13.56 MHz and 100 W of power for 10 minutes in a flowing oxygen atmosphere at a pressure of 650 mTorr. The probe is then dipped into a 25% sulfuric acid solution for 2 minutes to remove any oxidized copper. The part is then rinsed in flowing DI water for 30 seconds and dipped into an acidic palladium sulfate seeding bath (0.1 g/L PdSO₄ in 20 mL/L H2SO₄ aqueous solution) for 5 minutes. This tends to produce a dark tarnish of Pd atoms on the Cu surfaces. Finally, the parts are rinsed in DI water for 30 seconds to remove any excess Pd seed or acid.

The Cu surfaces should now be active and ready to be immersed into the electroless nickel (EN) bath. The EN bath used in the experimentation of the invention was ENPLATE NI426, which is a low phosphorus plating bath produced by Enthone Corporation. Operating conditions of the EN bath are given in Table 1. According to these conditions, a Ni—P phase diagram should indicate that no solid solubility of phosphorus in Ni at the plating temperature exists and that only a mixture of pure Ni and the intermetallic Ni₃P exists. However, because of the plating rate, it is kinetically impossible for the intermetallic phase to form. Therefore the plated film is a supersaturated alloy of Ni and P. This results in a very hard (650 HK100) deposit with a microcrystalline grain structure (grain sizes 2 to 6 nm).

The electroless plating bath is operated under constant agitation and filtration to ensure uniform and smooth deposits. Custom plating tanks and bath heaters were fabricated to accommodate the panels. At a pH of 6.2 and a bath temperature of 83 degrees C., the plating rate is between 15 and 18 μm/hr. Parts were left in the bath for 10 minutes to achieve a 2.5 μm film. The film thicknesses were confirmed using optical microscopy and SEM imaging. Conformal coverage of the underlying Cu produced a coherent and smooth Ni:P film.

After deposition of the Ni diffusion barrier, it is necessary to deposit a similar thickness of gold (Au) to ensure good electrical contact for testing. The gold layer is a two-step process where a first layer of immersion gold is deposited to a thickness of 0.3 μm followed by an electroless gold deposition of 2.2 μm. The immersion Au chemistry used is Oromerse MN® from Techinc Incorporated, and the electroless Au bath is the GoBright TMS-21® bath from Uyemura International Corporation. Both baths come premixed and ready to use. The operating details are given in Table 1 above.

A simple modification of the current probe fabrication process replaces the two-step bump/greyscale plating with a single electroless plating process. The new process can be broken down into three components: pre-plating bump and pin formation, probe removal and cleaning, and electroless deposition of Ni/Au layers.

The first stage of the probe fabrication process is the formation of copper bumps and greyscale pins. These should be formed using the standard process as a template with the following modifications. First, only Cu bump plating is required. The bump is formed with a standard height and width, as dictated by the original process. After Cu bump plating, the Cu film is cleaned and coated with a resist, as required for greyscale lithography and etching. Before greyscale etching, the bumps are protected with a thick resist coat applied by a brush method and air dried. The standard etch procedure is used to form greyscale pins. The final product is a four-up panel with Cu bumps on the Kapton side and greyscale pins on the opposite side.

At this point, the individual probes are cut from the four-up panel to reduce Ni and Au plating waste. Each probe is then cut from the panel and cleaned to ensure that all organics are removed before electroless plating begins. The electroless deposition of Ni and Au is then performed.

The following process and solutions, for example, may be used to produce flexible interposers according to the invention:
1. Dip parts into 25% H₂SO₄ for 2 minutes and rinse with DI water for 30 seconds
2. Dip parts into Pd seed solution for 4 minutes and rinse for 30 seconds
3. Dip parts into ENPLATE Ni426® plating solution for 12 minutes and rinse for 1 minute (the metal probes should be shiny and silver colored now)
4. Dip parts into Oromerse MN® solution for 30 minutes and rinse for 30 seconds (0.2_{—}0.3 μm Au film achieved)
5. Dip parts into Gobright® solution for 90 minutes (2.2_{—}2.3 μm film achieved)

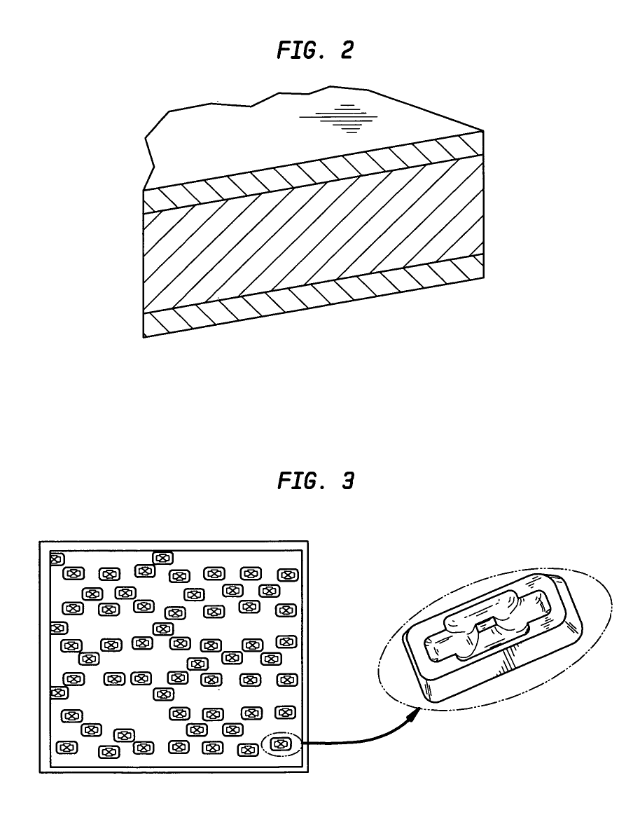

FIG. 2 shows an SEM micrograph of the cross section of a surface of the probe. The top two layers in the image are the electroless Au and Ni deposits. Note the uniformity of the coverage. The Ni layer measured approximately 3.0 μm and the Au layer measured approximately 2.5 μm. Although not shown, at higher magnifications the Ni is seen to penetrate into the micro-roughened Cu surface. This penetration forms a strong interface between the Ni and Cu surfaces.

FIG. 3 shows an image of an electrolessly plated probe with an inset, magnified image of a footprint. The probe pins show smooth deposits at high magnification.

The above described processes offer several advantages over other fabrication methods. For example, the underside of the probe that contacts the Kapton® film is plated with a protective Ni/Au layer. In standard electrolytic plating, this part of the probe would not be coated, and would therefore be subject to corrosion and other degradation. Acidic agents are typically used to clean currently available probes according to strict cleaning schedules in order to remove lead and tin deposits, for example. Such acidic agents are often a primary cause of corrosion on an underside of the probes. Eliminating the need for these acidic agents renders the probes fabricated by the processes described herein more reliable and more convenient as well.

The probes fabricated by the electroless plating processes described herein are more easily repaired than currently available probes as well, particularly where the probes have already been used and/or have suffered damage to the Ni/Au surface layer. Once a damaged probe is identified, it can be cleaned and re-plated with Ni/Au as the original Ni/Au layer wears thin or wears out. This process of repair can significantly increase the lifetime of an interposer, and can lower the cost of use as well.

Further, the probes fabricated by the electroless plating processes described herein may be produced in less steps than currently available interposers:. For example, where standard electrolytic plating methods are used, the front side of the interposer and the back side of the interposer are each separately plated. Thus, the electrolytic plating process requires two separate plating procedures. On the other hand, the electroless plating processes described herein coats both sides of the interposer at once, thereby saving a significant amount of processing steps.

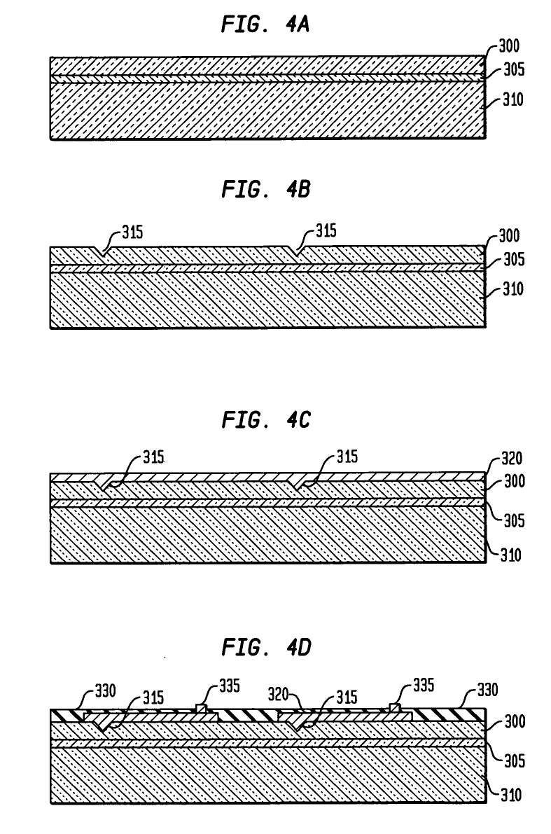

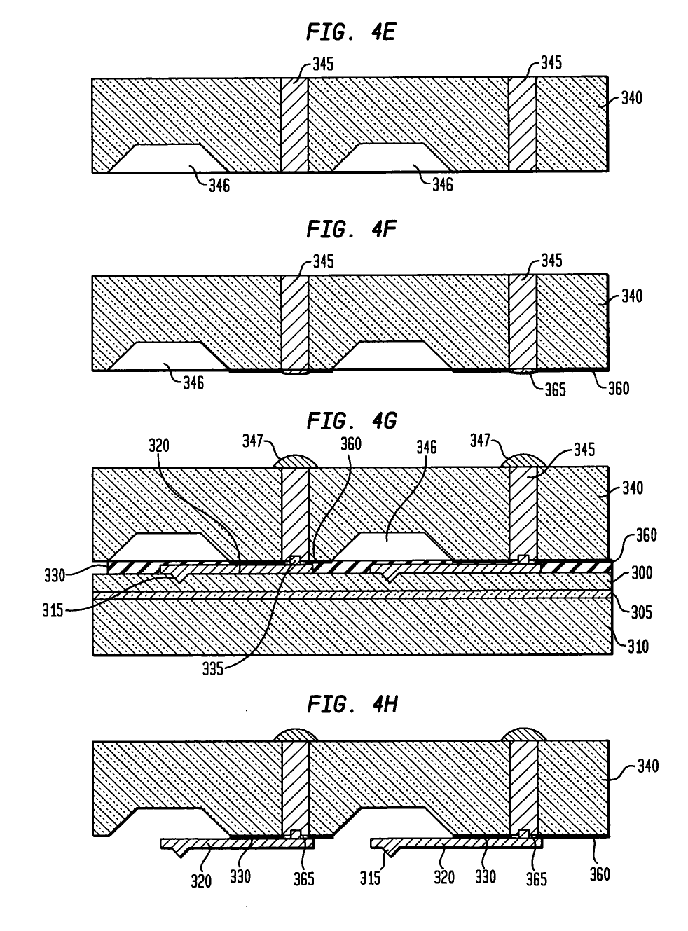

FIGS. 4A-4H, as will be described in more detail below, illustrate another embodiment of fabricating a flexible interposer according to the invention. In general, the interposer fabricating process illustrated in FIGS. 4A-4H use standard semiconductor processes and materials, as opposed to the more complex procedures and uncommon materials often used to produce currently available flexible interposers.

According to various embodiments of the invention, vias are produced through a silicon, or other type of semiconductor wafer. The vias are filled with a conductive material, for example, to permit a front-to-back connection between the vias and the underlying wafer substrate and a seed layer or other substrate surface. The via structure thus acts as an interposer to connect two substrates. Depending on the application, the via structures can be built on both sides of the wafer in order to better facilitate probing.

For example, when connecting to a solder pad a pin can be formed on one side of the interposer to connect to the filled via with a flexible lead. The flexible lead is rigid enough to puncture through oxides on the surface of a solder ball to accommodate any non-uniformity in heights. To create the pins, micromolds are first created by using silicon or other micro-machining techniques. These molds ate filled with a material, such as a metal, up to a prescribed thickness to create sharp pins. This molding technique provides advantages such as:
producing atomically sharp features using silicon or other single crystalline materials (GaAs, Ge, SiGe, and others);
permitting easier image replication using materials that are easily peeled away, such as Cu, that does not bond well with a Si mold;
providing cleaning of the mold using standard semi-conductor techniques; and
providing cheaper production costs.

The flexible leads are preferably created using either a flexible organic material coated with a conductive metal, or a metal with good electrical properties while possessing high tensile strength such as, for example, 450-620 MPa and most preferably 550 MPa. For example, copper beryllium could be used as the material for the flexible leads, or an elastic polymer having a metal or metallic coating could be used, although other flexible organic materials known in the art could as well be used as will be appreciated by the skilled artisan. Of course, the artisan will also readily appreciate that the leads could as well be comprised of a rigid material such as, Si or Si₃N₄, for example. This entire structure could then be transferred to the silicon interposer.

More specifically, FIGS. 4A-4H illustrate a process for fabricating a flexible silicon interposer according to various embodiments of the invention whereby FIG. 4A illustrates a thinned Si wafer 300 bonded to a handle wafer such as a quartz or a standard Si wafer 310 with an oxide or organic adhesion layer (e.g. Dupont KJ) 305 between them. FIG. 4B illustrates inverted pyramids 315 on a surface of the thinned wafer 300. The pyramids 315 may be formed using an anisotropic etch process, for example. The artisan will appreciate that additional pyramids, or other shapes, may be formed to comprise an array of small points sufficient to be used as leads to probe and penetrate oxides on a surface of a contact pad, for example. FIG. 4C illustrates a seed layer 320 and plate atop the surface of the thinned wafer 300 and filling the inverted pyramids 315. FIG. 4D illustrates an insulating layer 330 patterned over the seed layer 320 such that joining studs 335 are formed from the seed layer 320 and surrounded by the insulating layer 330. FIG. 4E illustrates a Si substrate 340 having vias 345 and anisotropically etched vias 346.

FIG. 4F illustrates an insulating surface 360 placed adjacent an underside surface of the Si substrate 340. Vias 365 created through the insulating surface 360 align with the vias 345 created in the Si substrate 340 and accept the joining studs 335 created from the seed layer atop the thinned wafer 300 when the Si wafer 340 is joined with the bonded thin wafer 300-oxide 305-standard wafer 310 part.

FIG. 4G illustrates the Si substrate 340 joined to the bonded thin wafer 300-oxide 305-standard wafer 310 part, whereby joining studs 335 are received in the vias 365 of the insulating layer 360 that are aligned with the vias 345 of the Si substrate 340. Contacts 347 are added to an exposed upper surface of the substrate 340. Thereafter, as FIG. 4H illustrates, the bonded thin wafer 300-oxide 305-standard wafer 310 are etched away, along with exposed portions of the seed layer 320 to leave a flexible Si interposer according to the invention.

The micro-molded interposer structures formed by the processes described above with respect to FIGS. 4A-4H use standard semiconductor processes and materials. These interposers are thus cheaper and easier to manufacture than existing interposers which are either hand-assembled or require non-standard processing of organic substrates. The interposers formed according to the processes set forth in FIGS. 4A-4H, for example, may also demonstrate improved pitch including smaller pitches than existing interposers exhibit. The interposer according to the invention may accommodate probing fine pitch pads having pitches of as little as 25 μm, for example. Further still, the processes set forth in FIGS. 4A-4H could also be used to serve as arrays of metallic atomic force microscope tips useful for materials analysis in addition to being used for forming interposers.

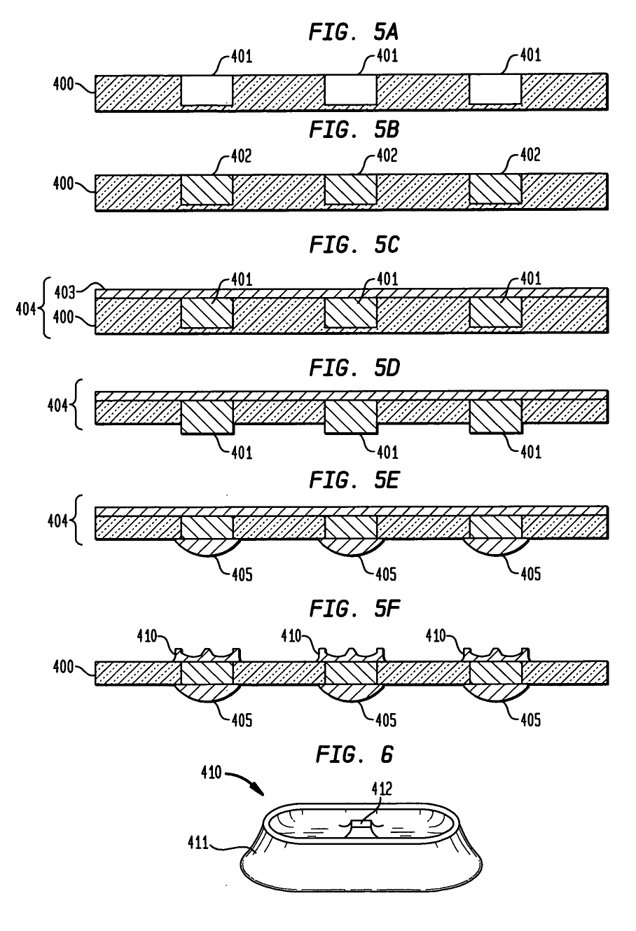

FIGS. 5A-5F illustrate a method for making a rigid interposer according to the invention. The rigid interposer accommodates the probing of flexible circuits that is often not accommodated by current interposer technologies. As shown in FIGS. 5A-5F, a wafer 400, for example a silicon wafer, is provided with vias 401. The vias may be etched as deep trenches within the wafer 400, for example, in conventional manner as known in the art. The vias 401 correspond to pad locations on the chip being tested and to pads located in packaging modules holding the chips. In FIG. 5B, the vias 401 are filled with a conductive material 402 to provide front to back connection of the vias with the pads of the chip and the packaging module. The conductive material may be copper, copper paste, or solder, for example, or other suitable conductive material known in the art.

In FIG. 5C a thick copper layer 403 is deposited over the wafer 400 and filled vias 401 to form a wafer/layer combination 404. As shown in FIG. 5D, the wafer/layer combination 404 is then thinned, if desired, using conventional techniques to expose the underside of the filled vias 401.

As shown in FIG. 5E, metal contacts 405 are then formed on the exposed vias 401 on the underside of the wafer. The metal contacts 405 may be in the form or shape of bumps, for example, for contacting the pads on the packaging module holding the chip. Of course, the artisan will appreciate that other shapes conducive to contacting the pads on the package holding the chip may be used as the metal contacts 405 according to the invention.

As shown in FIG. 5F, probes 410 are then formed on upper side of the wafer layer combination 404. The probes 410, shown in more detail in FIG. 6, contact the pads of the chip being tested. According to the embodiment of the probes 410 shown in FIG. 6, each probe 410 comprises a pad 411 with a pin 412 in the middle of the pad 411. The pad 411 may be a recessed well such that the pin 412 projects out from the well as shown in FIG. 6, for example. The outer perimeter of the pad 411 thus comprises a sharp, well-defined edge that in combination with the recessed well captures the solder pad of the chip while the central pin 412 punctures through oxides on the surface of the solder pad of the chip. Because the probe 410 is rigid and planar, when pressure is applied to the interposer against a flexible circuit during probing, the flexible circuit assumes the planarity of the interposer. As a result, a reliable connection between the pads of the chip being tested, the interposer, and the packaging module is accommodated.

To further enhance the ability of the probe pin 412 to puncture oxides on the surface of the solder pads of the chip, the probe pin 412 may be coated with a hard material. The hard material may be tungsten or titanium, for example, or other materials that can be electroplated, such as palladium-cobalt or palladium-nickel, for example.

Although the probes 410 may be comprised of other than silicon wafers according to the invention, the use of silicon wafers for the probes 410 minimizes expense as silicon wafers are readily available and understood in the semiconductor manufacturing industry. Likewise, the use of silicon wafers provides additional flexibility to the probes as additional structures such as wiring structures or other active devices, for example, may be provided on either side of the probes. Such additional structures can provide for advanced probing techniques including speed sorting.

Building the probes 410 on rigid substrates enable simplified alignment techniques relative to the solder pads of chips being tested or the packaging modules holding said chips. Additional and/or wider guide holes could be drilled along with the vias to enhance the mechanical alignment of the probes 410 with the chips and package modules. These holes would align the probe pattern with nanometer accuracy to capture dowel pins connected to the substrate, for example, for very fast and accurate alignment of the probe with the chip and packaging module.

While there has been shown and described what is considered to be preferred embodiments of the invention, it will, of course be understood that various modifications and changes in form or detail could readily be made without departing from the spirit and scope of the invention. It is therefore intended that the invention be not limited to the exact forms described and illustrated herein, but should be construed to cover all modifications that may fall within the scope of the appended claims.

What is claimed is:

1. A method for fabricating a flexible interposer, the method comprising:
pre-plating bump and pin formations on a probe panel, the bumps provided on one side and the pins provided on an etching side of the probe panel the one side being opposite the etching side;
cleaning a surface of the probe panel;
applying a photoresist layer for greyscale lithography and etching of the probe panel;
cutting probes from the probe panel;
seeding each of the probes with a first metal;
depositing an electroless layer comprised of a second metal on each of the probes by immersion seeding the probes in a bath provided with a second metal, the second metal being more noble than the first metal; and
depositing a third metal onto each of the electrolessly plated probes, wherein the third metal is more noble than the second metal.

2. The method of claim 1, wherein cleaning the surface further comprises:
stripping the surface of organics and photoresist;
oxygen ashing the surface;
soaking the surface in ethyl alcohol;
rinsing the surface with deionized water; and
rendering the surface catalytic.

3. The method of claim 2, further comprising holding the probe in a probe holder during the fabrication of the flexible interposer, wherein the probe holder is comprised of a polymer to minimize plating onto metals of the probe panel.

4. The method of claim 3, wherein the surface of the probe panel is Cu, the first metal is Pd, the second metal is Ni, and the third metal is Au.

5. The method of claim 1, wherein depositing the third metal is comprised of depositing a first immersion layer of the third metal onto the probe and then depositing a second electrolessly plating layer of the third metal onto the probe.

6. The method of claim 4, wherein the electroless plating bath is constantly agitated and filtered to accommodate more uniform and smooth deposits.

7. The method of claim 6, further comprising contacting all parts of the interposer probe with the electroless layers, whereby corrosion is minimized and electrical contact regions are isolated.

8. The method of claim 7, further comprising increasing the lifetime of each of the probes by cleaning, etching and re-plating the probes as needed.

9. The method of claim 1, wherein the electrolessly plated layers are deposited on all sides of the interposer at once.

10. A method of fabricating flexible interposers comprising:
bonding a thinned wafer to a handle wafer comprising one of quartz or a standard Si wafer with an oxide or organic adhesion layer therebetween;
etching inverted pyramids into an exposed surface of the standard wafer using an anisotropic etching process;
depositing a flexible lead seed layer atop the exposed surface of the standard wafer;
patterning an insulating layer over the seed layer to form joining studs from the seed layer;
providing a substrate having a top and bottom surface wherein one set of vias extends through the substrate between the top and bottom surfaces thereof, and another set of vias that are anisotropically etched along the bottom surface of the substrate;
filling the vias that extend between the top and bottom surface of the substrate with a conductive material;
providing an insulating surface along the bottom surface of the substrate, the insulating surface having vias that align with the vias extending through the substrate for receiving of the joining studs;
joining the substrate with the bonded thin wafer and standard wafer, whereby the joining studs are received in the vias of the substrate insulating layer and in the vias extending through the substrate;
adding contacts to the exposed upper surface of the substrate; and
etching away portions of the bonded thin wafer, standard wafer and seed layer to form the flexible interposer.

11. The method of claim 10, further comprising fabricating wiring structures on one or more surfaces of the interposer.

12. The method of claim 11, wherein the wiring structures are contacted using wirebonding techniques enabling advanced probing controls.

13. The method of claim 10, wherein the thinned wafer and the handle wafer are each comprised of Si.

14. The method of claim 10, wherein the thinned wafer and the handle wafer are each comprised of glass.

15. The method of claim 13, wherein the flexible lead is comprised of an elastic metal coated with a conductive metal the combination thereof having high tensile strength in the range of 450-620 Mpa.

16. The method of claim 13, wherein the flexible lead is comprised of an elastic polymer having a metal or metallic coating.

17. The method of claim 15, wherein the flexible lead is comprised one of BeCu and W.

18. The method of claim 13, wherein the flexible lead is comprised of a rigid material.

19. The method of claim 18, wherein the flexible lead is comprised of one of Si or Si₃N₄ having a conductive or metallic coating.

20. The method of claim 10, further comprising interposer probe pitches accommodating probing of fine pitch pads of as little as 25 μm.

21. The method of claim 10, wherein etching the inverted pyramids comprises etching multiple probe leads having pointed tips to capture and center a contact bump to be probed.

22. The method of claim 21, wherein etching the multiple probe leads comprises etching an array of small points for contacting the bump to be probed.

23. The method of claim 22, wherein patterning the insulating layer over the flexible lead comprises patterning an elastic polymer as the insulating layer.

24. The method of claim 10, further comprising facilitating mechanical alignment of the interposer with a component to be tested.

25. The method of claim 10, wherein the anisotropically etched inverted pyramids are etched to form molds.

26. The method of claim 25 in which each pyramid mold is filled with a conductive material by various techniques comprised of at least one of electroplating, electroless plating, and screening.

27. The method of claim 25 in which each pyramid mold is filled with a hard material consisting of the group of PdNi or PdCo.

28. A method for fabricating a rigid interposer, the method comprising:
etching deep trench vias in a wafer;
filling the vias with a conductive material;
depositing a metal layer over exposed upper portions of the vias and the wafer thereby forming a wafer/metal layer combination;
thinning the wafer/metal layer combination to expose lower portions of the filled vias;
providing metal contacts on the exposed lower portions of the vias;
patterning and etching rigid probes having pins projecting therefrom; and
attaching the rigid probes to the upper surface of the wafer and vias, wherein the vias and probes are located to align the pins with contact pads of a component to be tested.

29. The method of claim 28, further comprising fabricating wiring structures on one or more surfaces of the interposer.

30. The method of claim 29, wherein the wiring structures are contacted using wirebonding techniques enabling advanced probing controls.

31. The method of claim 28, wherein the wafer is comprised of Si.

32. The method of claim 31, wherein patterning and etching the rigid probes having pins includes providing a metal pad having sharp points accommodating probing contact pads with as little as a 25 μm pitch, the points penetrating oxides on the contact pads of the component to be tested.

33. The method of claim 32, wherein the pins comprise a hard material consisting of the group of PdNi and PdCo.

34. A flexible interposer comprising:
a probe seeded with a first metal;
an electrolessly plated layer comprised of a second metal overlying the first metal; and
an electrolessly plated layer comprised of a third metal overlying the second metal.

35. The flexible interposer of claim 34, wherein the probe is comprised from a Cu probe panel, the third metal is more noble than the second metal, and the second metal is more noble than the first metal.

36. The flexible interposer of claim 35, wherein the first metal is Cu seeded with Pd, the second metal is Ni, and the third metal is Au.

37. The flexible interposer of claim 36, wherein the electrolessly plated layers are deposited on all sides of the interposer at once.

38. The flexible interposer of claim 37, further comprising electrically isolated regions as a result of the electrolessly plated layers.

39. A flexible interposer comprising:
a thinned wafer;
a handle wafer;
an oxide barrier between the thinned wafer and the handle wafer, wherein the thinned wafer, oxide barrier and handle wafer are bonded together;
leads etched into an exposed surface of the standard wafer;
a flexible lead seed layer atop the exposed surface of the standard wafer and filling the leads etched into the standard wafer;
an insulating layer over the flexible leads and forming joining studs projecting from the flexible leads;
a substrate having a top and bottom surface with one set of vias extending through the substrate between the top and bottom surfaces, and another set of vias anisotropically etched into the bottom surface of the substrate, wherein the vias extending through the substrate are filled with a conductive material;
an insulating surface extending along the bottom surface of the substrate and having vias aligning with the vias extending through the substrate for receiving the joining studs; and
contacts provided at the exposed upper surface of the substrate, wherein portions of the bonded thin wafer, handle wafer and barrier are etched away to form the interposer.

40. The flexible interposer of claim 39, wherein the leads are cantilevered from the substrate.

41. The flexible interposer of claim 40, wherein the thinned wafer and the handle wafer are comprised of Si.

42. The flexible interposer of claim 41, wherein each flexible lead is comprised of an elastic metal coated with a conductive metal, the combination of the elastic metal and the conductive metal having high tensile properties.

43. The flexible interposer of claim 41, wherein each flexible lead is comprised of an elastic polymer having a metal or metallic coating.

44. The flexible interposer of claim 41, wherein each flexible lead is comprised of one of BeCu, W, Si and Si₃N₄.

45. The flexible interposer of claim 41, wherein each flexible lead is comprised of a rigid material.

46. The flexible interposer of claim 41, further comprising probe pitches accommodating probing fine pitch pads of as little as 25 μm.

47. The flexible interposer of claim 46, wherein the leads etched into the surface of the standard wafer are inverted pyramids having pointed tips to capture and center a contact bump to be probed.

48. The flexible interposer of claim 47, further comprising multiple leads comprising an array of small points for contacting the bump to be probed.

49. A rigid interposer comprising:
a wafer;
vias etched into the wafer;
a conductive material filling the vias;
a metal layer deposited over upper portions of the filled vias and the wafer, wherein lower portions of the filled vias are exposed;
metal contacts on the exposed lower portions of the vias;
probes having pins projecting therefrom attached to the upper portions of the wafer and filled vias, wherein the vias and probes are located to align the pins with contact pads of a component to be tested.

50. The rigid interposer of claim 49, further comprising wiring structures fabricated on one or more surfaces of the interposer.

51. The rigid interposer of claim 50, wherein the wiring structures are contacted using wirebonding techniques enabling advanced probing controls.

52. The rigid interposer of claim 51, wherein the advanced probing controls is speed sorting.

53. The rigid interposer of claim 49, wherein the wafer is comprised of Si.

54. The rigid interposer of claim 53, wherein the probes having pins comprise a metal pad having sharp points projecting therefrom and accommodating probing contact pads with as little as a 25 μm pitch, the points penetrating oxides on the contact pads of the component to be tested.

55. The rigid interposer of claim 54, wherein the pins comprise a hard material from the group consisting of PdNi and PdCo.
